(19) United States
(12) Patent Application Publication
(10) Pub. No.: US 2026/0293029 A1
(43) Pub. Date: Sep. 24, 2026

(54) POWER CONVERSION APPARATUS

(71) Applicant: LG INNOTEK CO., LTD., Seoul (KR)

(72) Inventors: Dong Keun YOON, Seoul (KR); Seung Min LEE, Seoul (KR); Kwang Soon JUNG, Seoul (KR)

(21) Appl. No.: 19/469,491

(22) PCT Filed: Jan. 26, 2024
(86) PCT No.: PCT/KR2024/001255

§ 371 Date: Sep. 26, 2025

(30) Foreign Application Priority Data
Mar. 29, 2023 (KR) 10-2023-0041550
Apr. 13, 2023 (KR) 10-2023-0049032

(51) Int. Cl. H05K 7/14; H01F 27/06; H01F 27/32; H01F 38/14; H02M 3/00; H05K 7/20

(52) U.S. Cl. CPC H05K 7/14324; H02M 3/003; H05K 7/20909; H01F 27/06; H01F 27/325; H01F 38/14

(57) ABSTRACT

A transformer according to an embodiment of the present invention comprises: a bobbin; a coil wound around the bobbin; and a core surrounding the coil and the bobbin, wherein the bobbin comprises an upper portion, a lower portion, and a middle portion which is between the upper and lower portions and around which the coil is wound, and holes are provided in the lower portion of the bobbin.

### TECHNICAL FIELD

The present invention relates to a power conversion apparatus.

### BACKGROUND ART

Generally, an eco-friendly vehicle is a vehicle equipped with a power source consisting of a drive motor that is powered by an engine and/or a battery. Accordingly, it is referred to as a vehicle that can improve its fuel efficiency during starting and/or acceleration through the power assist of the motor, which is operated by the battery's voltage, by applying a structure that appropriately combines this power source to the front wheels.

In eco-friendly vehicles, a power conversion apparatus (LDC: Low DC/DC Converter) is installed to rectify power from a high-voltage battery into direct current (DC). The power conversion apparatus switches the DC to create an alternating current (AC), which is then stepped up or down using components such as coils, transformers, and capacitors. Afterward, it is rectified back into DC and serves to supply electricity at a voltage suitable for each electrical load.

### DETAILED DESCRIPTION OF THE INVENTION

### Technical Subject

The technical problem to be solved by the present invention is to provide a power conversion apparatus.

### Technical Solution

In order to solve the above technical problems, a transformer according to an embodiment of the present invention comprises: a bobbin; a coil being wound around the bobbin; and a core surrounding the coil and the bobbin, wherein the bobbin comprises an upper portion, a lower portion, and a middle portion which is between the upper and lower portions and around which the coil is wound, and holes are provided in the lower portion of the bobbin.

The lower portion of the bobbin may include a recessed portion in which the hole is formed, and the recessed portion may include a plurality of recessed portions being formed spaced apart from an edge of the lower portion of the bobbin.

The upper portion of the bobbin includes an upper surface facing the core and a protruded portion being protruded outward from the upper surface, and the protruded portion can be overlapped with the coil from the upper portion toward the lower portion.

The hole may not be overlapped with the protruded portion in a direction from the upper portion to the lower portion.

The upper portion of the bobbin includes a guide wall being protrudedly formed between the upper surface and the protruded portion, and an inner surface of the guide wall can face the core.

In order to solve the above technical problems, a power conversion apparatus according to the present embodiment includes: a first housing; a first substrate being disposed in the first housing; and a transformer being disposed on the first substrate, wherein the transformer includes: a bobbin including a hollow portion; a coil being wound around the bobbin; and a core being disposed to surround the coil and the bobbin, wherein the bobbin includes an upper portion, a lower portion, and a middle portion on which the coil is wound between the upper portion and the lower portion, and wherein the transformer can be coupled to the first housing as a screw is disposed in a hole being formed in the lower portion of the bobbin.

A fixing member is inserted from the outside to the inside of the first housing, and the screw being disposed in the hole of the bobbin can be combined with the fixing member.

It may include: a second housing being coupled to the first housing; and a second substrate being disposed in the second housing, wherein the second substrate may include a support member being disposed at a position corresponding to the transformer.

The support member includes a first pad being disposed on the second substrate and a second pad being disposed on the first pad, and the second pad may be made of an elastic material or a sponge material.

The upper portion of the bobbin includes an upper surface facing the core and a protruded portion being protruded outward from the upper surface, and the protruded portion can be overlapped with the coil from the upper portion toward the lower portion.

The hole of the bobbin may not be overlapped with the protruded portion in a direction from the upper portion to the lower portion.

The upper portion of the bobbin includes a guide wall being protruded between the upper surface and the protruded portion, and an inner surface of the guide wall can face the core.

### Advantageous Effects

According to the present embodiments, a bulky transformer can be coupled to a housing to minimize warping of the substrate, and the influence of vertical vibration can be reduced through a support member.

In addition, heat dissipation performance can be improved by placing the heat generating component in an area being overlapped with the fan module, and air circulation can be concentrated on the heat sink by placing components on both side surfaces of the heat sink and structures at the front and rear.

In addition, space efficiency can be improved by allowing additional components to be disposed by forming a gap in the lower portion of the switching module.

In addition, by symmetrically placing each component with respect to the heatsink, it is possible to optimize the circuit design and balance the weight.

In addition, by integrating a plurality of switching device units into a single heatsink, it is possible to lower the maximum temperature of components within the switching module and achieve thermal equilibrium, thereby optimizing heat dissipation performance.

### BRIEF DESCRIPTION OF DRAWINGS

FIG. 1 is a perspective view of a power conversion apparatus according to the present embodiment.

FIG. 2 is an exploded perspective view of a power conversion apparatus according to the present embodiment.

FIG. 3 is an exploded perspective view of a power conversion apparatus according to the present embodiment.

FIG. 4 is a drawing of a first assembly according to the present embodiment.

FIG. 5 is a drawing of a second assembly according to the present embodiment.

FIG. 6 is a front view of a first switching module according to the present embodiment.

FIG. 7 is a perspective view of a first switching module according to the present embodiment.

FIG. 8 is a perspective view of a fourth switching module according to the present embodiment.

FIG. 9 is a perspective view of the fourth switching module viewed from a different angle than that of FIG. 8.

FIG. 10 is a perspective view of a transformer according to the present embodiment.

FIG. 11 is a perspective view of a bobbin according to the present embodiment.

FIG. 12 is a drawing illustrating an arrangement of a transformer according to the present embodiment.

FIG. 13 is a drawing of first and second assemblies according to the present embodiment.

FIG. 14 is a cross-sectional view taken along line A of FIG. 13.

FIG. 15 is a cross-sectional view taken along line B of FIG. 13.

FIG. 16 is a partial drawing of a second assembly according to the present embodiment.

FIG. 17 is a partial drawing of a second assembly according to the present embodiment.

### BEST MODE

Hereinafter, preferred embodiments of the present invention will be described in detail with reference to the accompanying drawings.

However, the technical idea of the present invention is not limited to some embodiments to be described, but may be implemented in various forms, and inside the scope of the technical idea of the present invention, one or more of the constituent elements may be selectively combined or substituted between embodiments.

In addition, the terms (including technical and scientific terms) used in the embodiments of the present invention, unless explicitly defined and described, can be interpreted as a meaning that can be generally understood by a person skilled in the art, and commonly used terms such as terms defined in the dictionary may be interpreted in consideration of the meaning of the context of the related technology.

In addition, terms used in the present specification are for describing embodiments and are not intended to limit the present invention. In the present specification, the singular form may include the plural form unless specifically stated in the phrase, and when described as “at least one (or more than one) of A and B and C”, it may include one or more of all combinations that can be combined with A, B, and C.

In addition, in describing the components of the embodiment of the present invention, terms such as first, second, A, B, (a), and (b) may be used.

These terms are merely intended to distinguish the components from other components, and the terms do not limit the nature, order or sequence of the components.

And, when a component is described as being ‘connected’, ‘coupled’ or ‘interconnected’ to another component, the component is not only directly connected, coupled or interconnected to the other component, but may also include cases of being ‘connected’, ‘coupled’, or ‘interconnected’due that another component between that other components.

In addition, when described as being formed or disposed in “on (above)” or “below (under)” of each component, “on (above)” or “below (under)” means that it includes not only the case where the two components are directly in contact with, but also the case where one or more other components are formed or disposed between the two components. In addition, when expressed as “on (above)” or “below (under)”, the meaning of not only an upward direction but also a downward direction with respect to one component may be included.

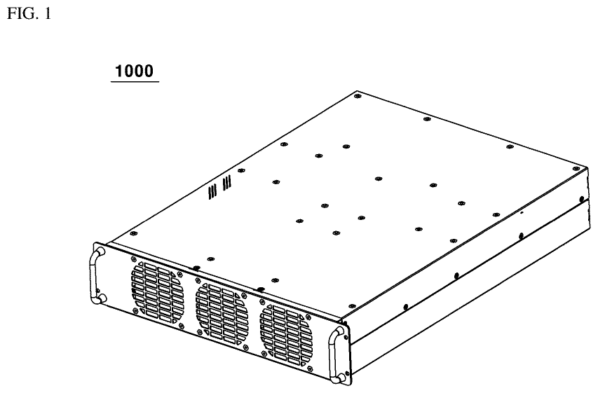

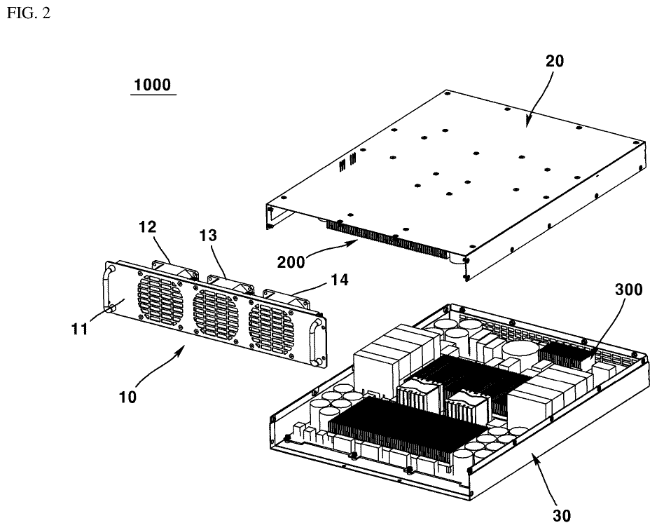

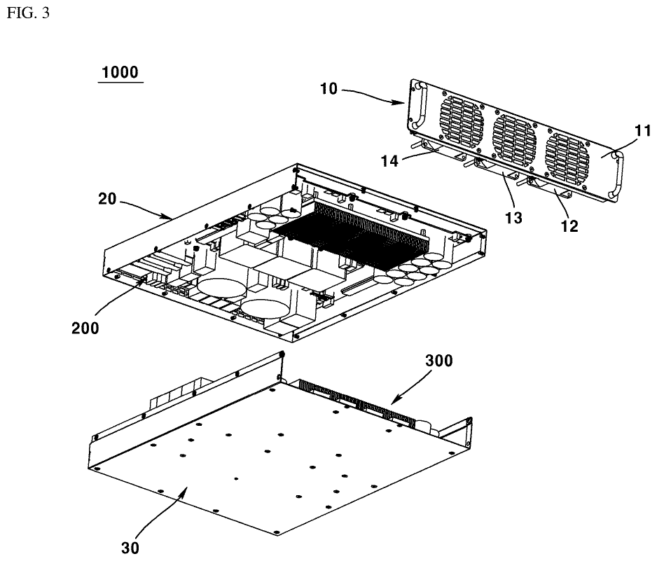

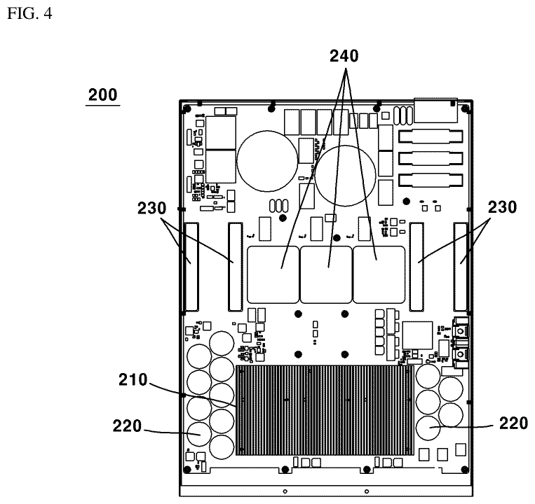

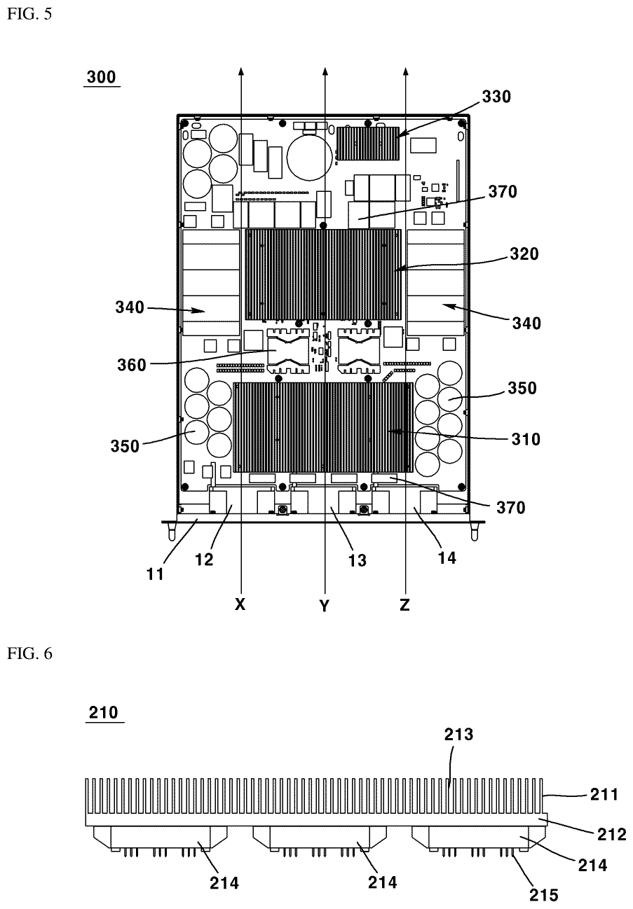

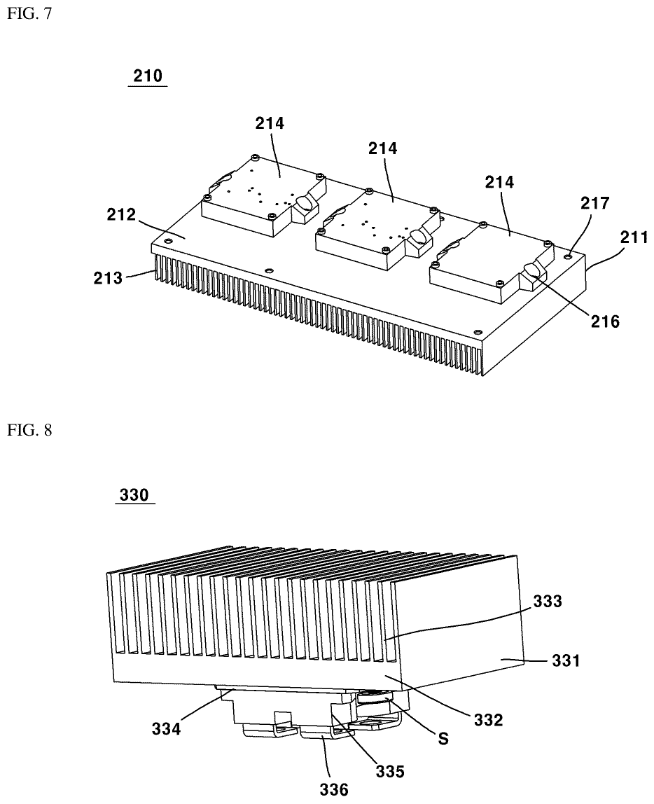

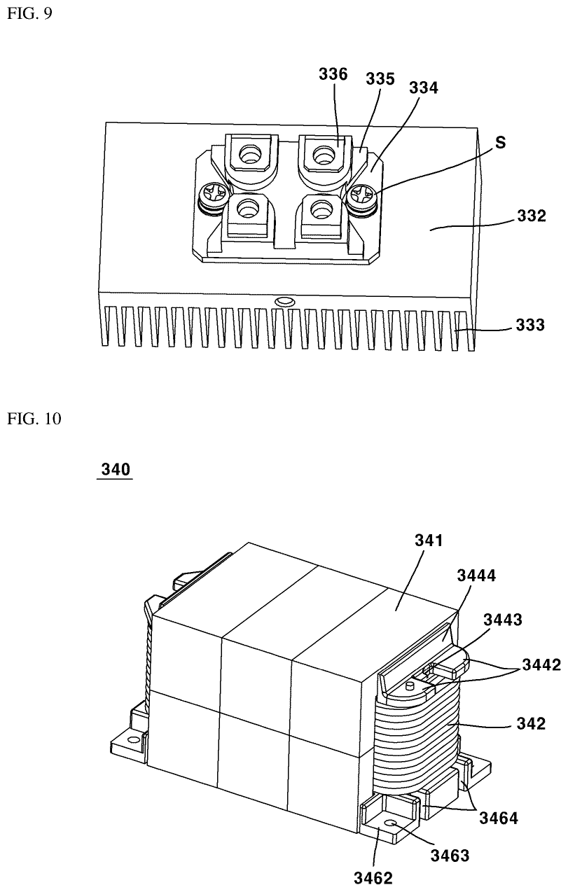

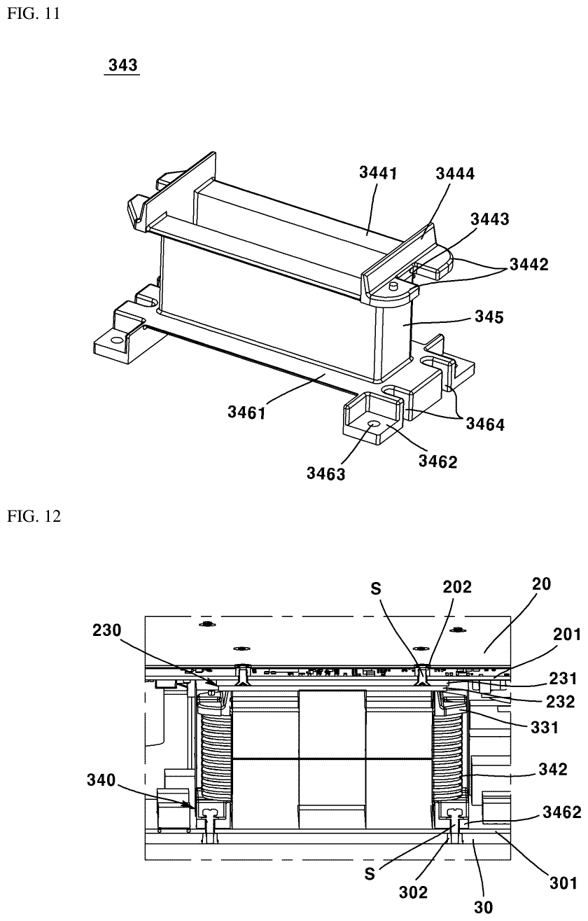

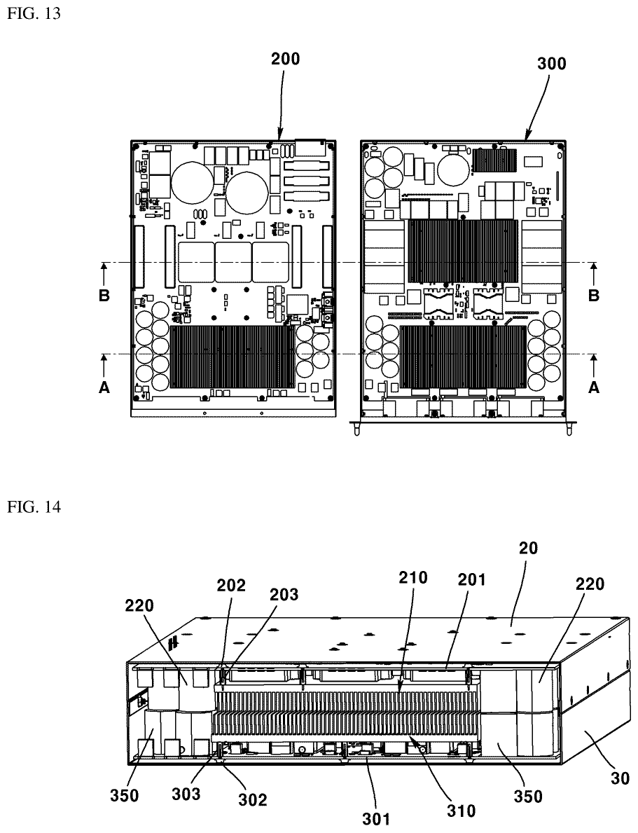

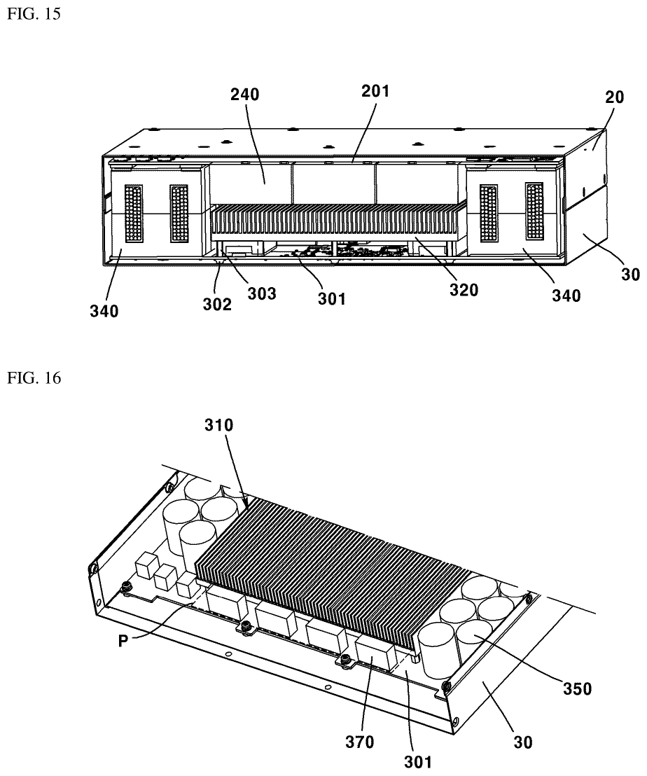

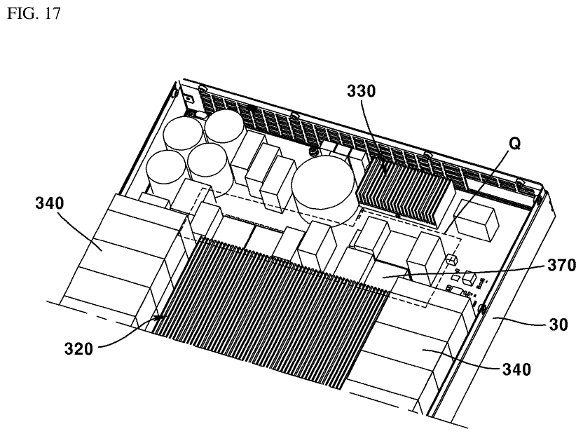

FIG. 1 is a perspective view of a power conversion apparatus according to the present embodiment; FIG. 2 is an exploded perspective view of a power conversion apparatus according to the present embodiment; FIG. 3 is an exploded perspective view of a power conversion apparatus according to the present embodiment; FIG. 4 is a drawing of a first assembly according to the present embodiment; FIG. 5 is a drawing of a second assembly according to the present embodiment; FIG. 6 is a front view of a first switching module according to the present embodiment; FIG. 7 is a perspective view of a first switching module according to the present embodiment; FIG. 8 is a perspective view of a fourth switching module according to the present embodiment; FIG. 9 is a perspective view of the fourth switching module viewed from a different angle than that of FIG. 8; FIG. 10 is a perspective view of a transformer according to the present embodiment; FIG. 11 is a perspective view of a bobbin according to the present embodiment; FIG. 12 is a drawing illustrating an arrangement of a transformer according to the present embodiment; FIG. 13 is a drawing of first and second assemblies according to the present embodiment; FIG. 14 is a cross-sectional view taken along line A of FIG. 13; FIG. 15 is a cross-sectional view taken along line B of FIG. 13; FIG. 16 is a partial drawing of a second assembly according to the present embodiment; and FIG. 17 is a partial drawing of a second assembly according to the present embodiment.

The power conversion apparatus 1000 according to the present embodiment may include a fan module 10, a first assembly 200 being disposed in a first housing 20, and a second assembly 300 being disposed in a second housing 30.

The power conversion apparatus 1000 according to the present embodiment may be a power module. The power conversion apparatus 1000 may be a power supply unit (PSU). The power conversion apparatus 1000 may be a power circuit device that generates required output power from input power. The power conversion apparatus 1000 may be a device that supplies power required for charging a battery, and may be a device that converts input commercial AC power into DC power required by a battery and outputs it.

The power conversion apparatus 1000 may comprise an EMI (Electromagnetic Interference) filter being connected to AC power being supplied to the power conversion apparatus, a PFC (Power Factor Correction) unit being connected to the EMI filter, and a DC/DC converter unit being connected to the PFC unit. Specifically, the EMI filter can remove noise from the AC power. The PFC unit matches the voltage and rectification of the AC power rectified by the EMI filter to be in-phase. The PFC unit may be referred to as an AC/DC converter unit. The PFC unit boosts the input power after improving the power factor. Thereafter, the DC/DC converter unit converts the power into DC power that meets the specifications of the load being supplied with the power.

The power conversion apparatus 1000 may include components such as a fan module, an EMI filter, an AC socket, a PFC section, a DC-DC converter unit, and a flyback converter, and each component may influence each other depending on the size and mounting position of each component. Accordingly, the overall size of the power conversion apparatus 1000 may vary.

The fan module 10 may be disposed in front of the power conversion apparatus 1000. The fan module 10 may be disposed on one side of the power conversion apparatus 1000. The fan module 10 may cool components being disposed at one side of the power conversion apparatus 1000. A ventilation hole may be disposed at the rear of the power conversion apparatus 1000, opposite to where the fan module 10 is disposed. As the fan module 10 operates, external air may be introduced into the interior to cool components that generate heat. The direction connected from the fan module 10 to the ventilation hole may be referred to as a first direction. The direction perpendicular to the first direction may be referred to as a second direction.

The fan module 10 may include at least one fan being disposed in the panel 11. The fan module 10 may include first to third fans 12, 13 and 14 being disposed in a row on the panel 11. The first to third fans 12, 13 and 14 may be disposed spaced apart from one another. The first to third fans 12, 13 and 14 may be disposed sequentially. The second fan 13 may be disposed between the first fan 12 and the third fan 14. The second fan 13 may be disposed at the center portion of the panel 11. The first fan 12 may be disposed closer to the second fan 13 than the side plates of the first housing 20 and the second housing 30. The third fan 14 may be disposed closer to the second fan 13 than the side plates of the first housing 20 and the second housing 30. The first fan 12 and the second fan 13, and the second fan 13 and the third fan 14 may be disposed at equal intervals.

The second assembly 300 may be disposed in the second housing 30. The second housing 30 may include a lower plate on which the second assembly 300 is disposed, and two side plates being extended vertically from both side surfaces of the lower plate. Components constituting a DC/DC converter unit may be disposed in the second assembly 300. The second assembly 300 may receive DC power from the first assembly 200, convert the DC power into power suitable for charging the battery, and output the converted power to the battery.

The power conversion apparatus 1000 may have an overall hexahedral shape in which the side plates of the first housing 20 and the second housing 30 are connected to each other and a fan module 10 is disposed at the front. However, the present invention is not limited thereto, and the shape of the power conversion apparatus 1000 may be modified in various ways. In the power conversion apparatus 1000, the first assembly 200 and the second assembly 300 may be disposed to face each other. The components disposed in the first assembly 200 and the components being disposed in the second assembly 300 may be disposed to face each other.

The first assembly 200 may be an assembly in which components constituting an AC/DC converter unit are disposed on a first substrate 201. The components being disposed on the first substrate 201 may include a first switch module 210, a first capacitor 220, an inductor 240, a support member 230, and may include an input terminal, an EMI filter, and the like.

The first switch module 210 may be disposed closest to the fan module 10. An inductor 240 may be disposed at the rear of the first switch module 210. Since the first switch module 210 and the inductor 240 are components that generate heat among the components included in the first assembly 200, they may be disposed closest to the fan module 10. Since the plurality of fans included in the fan module 10 are densely disposed in the central portion, the heat-generating components included in the first assembly 200 may be disposed in a direction facing the fans being disposed in the central portion. Through this, the heat dissipation effect can be increased by intensively generating air circulation in the central portion where the heat-generating components are disposed.

A virtual line X connecting from the center of the first fan 12 to the ventilation hole, a virtual line Y connecting from the center of the second fan 13 to the ventilation hole, and a virtual line Z connecting from the center of the third fan 14 to the ventilation hole may be defined. The first switch module 210 can be overlapped with at least two among the virtual lines X, Y, and Z. The plurality of inductors 240 can be overlapped with at least two among the virtual lines X, Y, and Z. The first switch module 210 can be disposed to be overlapped with at least two fans in the first direction connecting the fan module 10 and the ventilation hole. The plurality of inductors 240 may be disposed to be overlapped with at least two fans in the first direction connecting the fan module 10 and the ventilation hole.

First capacitors 220 may be disposed on both sides of the first switch module 210. The first capacitors 220 may be disposed in multiple rows to serve as barriers to concentrate air flow on the first switch module 210. For example, the first capacitors 220 may be disposed in two rows, but may be disposed in an alternating manner.

On both sides of the inductor 240, a support member 230 that supports a transformer 340 of a second assembly 300 to be described later may be disposed. By combining the first housing 20 and the second housing 30, the transformer 340 of the second assembly 300 is disposed on both sides of the inductor 240, and the transformer 340 of the second assembly 300 can serve as a barrier to concentrate the air flow on the inductor 240.

Referring to FIGS. 6 and 7, the first switch module 210 may include a heat sink 211 and a device unit 214. Although the heat sink 211 and the device unit 214 are described as a single component forming the first switch module 210, the heat sink 211 and the device unit 214 may each be separate configurations. The first switch module 210 may be formed with the same configuration as the second switch module 310 and the third switch module 320.

The number of device units being disposed on the heat sink of the first to third switching modules 210, 310 and 320 may vary depending on the size. Since the configurations included in the first to third switching modules 210, 310 and 320 may be the same, the description of the second and third switching modules 310 and 320 is omitted, as the description of the first switching module 210 will apply to them as well.

The heat sink 211 may include a base 212 on which a device unit 214 is placed on one surface, and heat dissipation fins 213 protrudingly formed on the other surface of the base 212. A plurality of heat dissipation fins 213 may be formed parallel to each other to form a flow path through which air may flow in a recessed area. The flow path formed between the plurality of heat dissipation fins 213 may be formed in a straight line from the fan module 10 to the ventilation hole. The plurality of heat dissipation fins 213 may be formed to be extended in a first direction. The plurality of heat dissipation fins 213 may be formed parallel to each other. A plurality of grooves formed between the plurality of heat dissipation fins 213 may be formed parallel to each other.

One surface of the base 212 may include a spacer hole 217 to which a spacer 203 is coupled. The spacer 203 may be disposed in the spacer hole 217 and fixed by a pop nut 202 being inserted from the outer surface of the first housing 20. The spacer 203 may be disposed in the spacer hole 217 and fixed by a screw being inserted from the outer surface of the first substrate 201. The spacer 203 may be disposed at an edge of one surface of the base 212 and may support the first switch module 210.

When the first switch module 210 is disposed on the first substrate 201, the spacer 203 can support the first switch module 210 so that a gap is formed between one surface of the base 212 and the first substrate 201. Additional components can be disposed in the gap formed between one surface of the base 212 and the first substrate 201. Additional components can be disposed in the gap where the device unit 214 is not disposed between one surface of the base 212 and the first substrate 201.

The device unit 214 can be disposed on one surface of the base 212. A plurality of device units 214 can be disposed spaced apart from one another on one surface of the base 212. The device unit 214 may include a frame and a plurality of switching elements being mounted inside the frame. The frame of the device unit 214 can be made of an insulating material. Various switching elements and rectifier diodes can be mounted on the device unit 214. The switching elements included in the device unit 214 can secure an insulating distance by being disposed inside the frame made of an insulating material.

By arranging multiple device units 214 on a single heat sink 211, the heat being generated from the device units 214 can be integrated and managed. From the perspective of thermal management of the power conversion apparatus 1000, it may be more stable for the temperature of the entire device unit to increase rather than for a single device unit to overheat. This has the effect of lowering the maximum heat generation temperature being generated from multiple device units.

One surface of the device unit 214 may include a plurality of pins 215 connected to the first substrate 201. A plurality of switches of the device unit 214 may be electrically connected to the first substrate 201 through the plurality of pins 215. The device unit 214 may include a coupling hole 216. The frame of the device unit 214 may include the coupling hole 216. The device unit 214 may be coupled to the heat sink 211 through a screw being coupled to the coupling hole 216.

Referring to the P area of FIG. 16 and the Q area of FIG. 17, at least one structure 370 may be disposed on one or the other side of the switching module in a first direction connecting the fan module 10 and the ventilation hole. The structure may be disposed in a direction facing the fan module 10 in the switching module being disposed closest to the fan module 10. The structure may be disposed in a direction facing the ventilation hole in the switching module being disposed farthest from the fan module 10. Here, the structure may be an electronic component or element, and may be, for example, a film capacitor.

The structure 370 can prevent air from flowing through the gap between the base 212 and the first substrate 201 and focus air circulation by the fan module 10 on the heat sink 211. The height of the structure 370 from the first substrate 201 can be greater than the spacer 203 and less than the base 212. By appropriately arranging structures 370 having various heights, air circulation can be focused on the switching module.

The second assembly 300 may be an assembly in which components constituting a DC/DC converter unit are disposed on a second substrate 301. The components being disposed on the second substrate 301 may include a second switch module 310, a third switch module 320, a fourth switch module 330, a transformer 340, a second capacitor 350, a heat generating component 360, and a structure 370.

The second switch module 310 may be disposed closest to the fan module 10. The third switch module 320 may be disposed at the rear of the second switch module 310. A heat generating component 360 may be disposed between the second switch module 310 and the third switch module 320. Here, the heat generating component 360 may be a resonant inductor. The fourth switch module 330 may be disposed at the rear of the third switch module 320.

The second to fourth switching modules 310, 320 and 330 are components that generate heat among the components included in the second assembly 300, and thus can be disposed adjacent to the fan module 10. Since the plurality of fans included in the fan module 10 are densely disposed in the central portion, the heat-generating components included in the second assembly 300 can be disposed in a direction facing the fans being disposed in the central portion. Through this, the heat dissipation effect can be enhanced by intensively generating air circulation in the central portion where the heat-generating components are disposed.

The second switch module 310, the third switch module 320, and the heat generating component 360 may be overlapped with at least two among the virtual lines X, Y, and Z. The fourth switch module 330 may be overlapped with at least one of the virtual lines X, Y, and Z. The second switch module 310, the third switch module 320, and the heat generating component 360 may be disposed to be overlapped with at least two fans in a first direction connecting the fan module 10 and the ventilation hole. The fourth switch module 330 may be disposed to be overlapped with at least one fan in a first direction connecting the fan module 10 and the ventilation hole.

The second to fourth switching modules 310, 320 and 330 may be disposed to be overlapped with one another in a first direction. Different switching modules may be disposed to not overlap each other in a second direction that is perpendicular to the first direction. Among the second to fourth switching modules 310, 320 and 330, the closer they are disposed to the fan module 10, the larger the size of the heat sink may be. When the second switch module 310, the third switch module 320, and the fourth switch module 330 are disposed sequentially from the fan module 10, the heat sink of the second switch module 310 may be larger than the heat sink of the third switch module 320, and the heat sink of the third switch module 320 may be larger than the heat sink of the fourth switch module 330. Through this, the heat dissipation effect of heat being generated from each switching module can be increased.

Second capacitors 350 may be disposed on both sides of the second switch module 310. The second capacitors 350 may be disposed in multiple rows to serve as barriers so that the air flow is concentrated on the second switch module 310. For example, the second capacitors 350 may be disposed in two rows, but may be disposed in an alternating manner. Transformers 340 may be disposed on both sides of the third switch module 320. The height of the transformers 340 with respect to the second substrate 301 may be formed higher than the height of the third switch module 320 so that the transformers may serve as barriers so that the air flow is concentrated on the third switch module 320.

At least one of the first to fourth switching modules 210, 310, 320 and 330 may be disposed on an imaginary line that equally divides the substrate in half in a second direction that is perpendicular to the first direction connecting the fan module 10 and the ventilation hole. At least one of the first to fourth switching modules 210, 310, 320 and 330 may be disposed on an imaginary Y line that connects the fan disposed at the center of the fan module 10 to the ventilation hole. At least one of the first to fourth switching modules 210, 310, 320 and 330 may be disposed at the center portion of the substrate. Through this, weight imbalance of the power conversion apparatus 1000 can be prevented, and an area for circuit connection can be secured by symmetrically arranging the circuits. In addition, the heat dissipation effect can be enhanced by increasing the eddy current, and imbalance in the heat dissipation flow can be prevented.

FIG. 14 is a cross-sectional view taken along line A of FIG. 13, and FIG. 15 is a cross-sectional view taken along line B of FIG. 13. The heat generating component included in the power conversion apparatus 1000 is disposed in the central portion, and components other than the heat generating component can be disposed in a structure symmetrical up and down or left and right with respect to the heat generating component.

In the cross-sectional view of FIG. 14, the first switch module 210 and the second switch module 310 may be disposed to face each other, and the first capacitor 220 and the second capacitor 350 may be disposed to face each other. The first capacitor 220 and the second capacitor 350 may be disposed to be in contact with each other, so that the gap between the first capacitor 220 and the second capacitor 350 may be minimized. The first capacitor 220 and the second capacitor 350 may be disposed close to each other, so that the gap between the first capacitor 220 and the second capacitor 350 may be minimized. Through this, the first capacitor 220 and the second capacitor 350 can serve as a barrier, thereby inducing air circulation to be concentrated in the groove between the heat dissipation fins of the first switch module 210 and the groove between the heat dissipation fins of the second switch module 310 when the fan module 10 is in operation.

In the cross-sectional view of FIG. 15, the third switch module 320 and the inductor 240 are disposed to face each other, and a transformer 340 may be disposed on each side of the third switch module 320 and the inductor 240. A space may be formed between the third switch module 320 and the inductor 240. The size of the transformer 340 may be formed to correspond to the space between the first substrate 201 and the second substrate 301. Through this, the transformer 340 may serve as a barrier, thereby inducing air circulation to be concentrated in the grooves between the heat dissipation fins of the third switch module 320 and the space between the third switch module 320 and the inductor 240 when the fan module 10 is in operation.

Referring to FIGS. 8 and 9, the fourth switch module 330 may comprise a heat sink 331, a pad 334, a device unit 335, and a terminal portion 336. The fourth switch module 330 may be an O-ring diode being connected to an output-side capacitor.

The heat sink 331 may include a base 332 on which a device unit 335 is disposed on one surface, and heat dissipation fins 333 protrudingly formed on the other surface of the base 332. The heat sink 331 may be referred to as a heat sink. A plurality of heat dissipation fins 333 may be formed parallel to each other to form a flow path through which air may flow in a recessed area. The flow path formed between the plurality of heat dissipation fins 333 may be formed in a straight line from the fan module 10 to the ventilation hole. The plurality of flow paths formed between the plurality of heat dissipation fins 333 may be formed parallel to each other.

A pad 334 may be disposed between the base 332 and the device unit 335. The pad 334 may be an insulating pad. The device unit 335 may be disposed on the pad 334. Various switching elements and O-ring diodes may be mounted on the device unit 335. The device unit 335 may have a case shape and may have various switching elements and O-ring diodes mounted therein. One surface of the device unit 335 may include a terminal portion 336 connected to the first substrate 201. The device unit 335 may include a plurality of protruded portions, and the terminal portions 336 may be disposed on the plurality of protruded portions. The device unit 335 may include a coupling hole. The device unit 335 may be coupled to the heat sink 331 through a screw S being coupled to the coupling hole.

The transformer 340 may comprise a core 341, a coil 342, and a bobbin 343.

The bobbin 343 may have a hollow shape and comprise an upper portion 3441, a middle portion 3451, and a lower portion 3461. A coil 342 may be wound around the middle portion 3451. The coil 342 may include a primary coil being wound around the middle portion 3451 and a secondary coil being wound around the primary coil. The coil 342 may include a primary coil being wound around the middle portion 3451, adjacent to the upper portion 3441, and adjacent to the lower portion 3461. The core 341 may include an upper core being formed to surround the upper portion 3441 and the coil 342 of the bobbin 343, and a lower core being formed to surround the lower portion 3461 and the coil 342. The upper core and the lower core may be separate configurations or may be formed as a single configuration.

The upper portion 3441 of the bobbin 343 may include an upper surface being contacted with the core 341. The bobbin 343 may comprise a protruded portion 3442 being protruded outwardly from the upper surface. The bobbin 343 may comprise a protruded portion 3442 being extended outwardly from the upper surface.

The lower surface of the protruded portion 3442 may face the coil 342. The protruded portion 3442 may be overlapped with the coil 342 in a direction from the upper portion to the lower portion. The protruded portion 3442 may include two protruded portions 3442 being protruded from the guide wall 3444. A fixing groove 3443 may be formed between the two protruded portions 3442. The fixing groove 3443 may serve to support the wire terminal being extended from the coil 342 to be caught and fixed.

The outer side surface of the protruded portion 3442 may be formed in a round shape. The outer side surface of the protruded portion 3442 may be formed in a chamfer shape. The protruded portion 3442 may be formed more inward than the recessed portion 3462 of the lower portion 3461 of the bobbin 343. The hole 3463 of the recessed portion 3462 may not be overlapped with the protruded portion 3442 in a direction from an upper portion to a lower portion. Through this, when a screw S is coupled to the hole 3463 of the recessed portion 3462 in a direction from an upper portion to a lower portion, interference caused by the protruded portion 3442 can be prevented.

The bobbin 343 may include a guide wall 3444 being formed between the upper surface and the protruded portion 3442. The bobbin 343 may include a guide wall 3444 being protruded upward between the upper surface and the protruded portion 3442. The guide wall 3444 may be formed between the upper surface and the protruded portion 3442. The inner surface of the guide wall 3444 may be in contact with the core 341. The inner surface of the guide wall 3444 may face the core 341. The guide wall 3444 may serve to support the outer side surface of the core 341 to prevent the core 341 from moving or separation.

The lower portion 3461 of the bobbin 343 may include a recessed portion 3462 being formed downwardly at an edge. The lower portion 3461 of the bobbin 343 may include a recessed portion 3462 being formed downwardly at a corner. A hole 3463 penetrating the recessed portion 3462 may be formed in the recessed portion 3462. A screw S may be coupled to the hole 3463 being formed in the recessed portion 3462, and the screw S may be coupled to a pop nut 302 being disposed in the second substrate 301 and the second housing 30.

Through this, the transformer 340 can be fixedly connected to both the second substrate 301 and the second housing 30. Since the transformer 340 is a large and heavy component among the components disposed on the second assembly 300, when it is fixed only to the second substrate 301, the second substrate 301 may warp and damage may occur to the components being disposed on the second substrate 301. Therefore, by doubly fixing the transformer 340 to the second substrate 301 and the second housing 30, the transformer 340 can be stably disposed.

The lower portion 3461 of the bobbin 343 may include a guide groove 3464 being formed on the opposite side of the protruded portion 3442 of the upper portion 3441. The lower portion 3461 of the bobbin 343 may include a guide groove 3464 being formed between two recessed portions 3462 of adjacent corners. The guide groove 3464 may include a plurality of guide grooves 3464 being spaced apart from each other. The guide groove 3464 may be overlapped with the coil 342. The guide groove 3464 may be formed to facilitate the coil 342 winding operation.

The support member 230 being disposed in the first assembly 200 may be disposed to be in contact with the transformer 340. The support member 230 may be disposed to be in contact with the core 341 on the upper portion side of the transformer 340. The support member 230 may be disposed to be in contact with the transformer 340 to prevent upward movement of the transformer 340 and vertical vibration of the transformer 340.

The support member 230 may include a first pad 231 being disposed on the first assembly 200 and a second pad 232 being disposed on the first pad 231. The first pad 231 may be made of a plastic material or a silicone material. The second pad 232 may be made of an elastic material or a sponge material. The first pad 231 may include a hole penetrating the first pad 231. The support member 230 may be fixed to the first assembly 200 by being screw-coupled to the hole of the first pad 231. The screw may be fixed to the hole of the first pad 231 by being coupled with a pop nut 202 being inserted into the first housing 20. The hole of the first pad 231 may be formed in a chamber shape. The screw being disposed on the first pad 231 may be disposed inside the hole so as not to be protruded outwardly from the first pad 231. A second pad 232 may be attached onto the first pad 231. An adhesive may be disposed between the first pad 231 and the second pad 232.

Those skilled in the art related to the present embodiment will understand that the above-described description can be implemented in a modified form without departing from the essential characteristics thereof. Therefore, the disclosed methods should be considered from an illustrative rather than a restrictive perspective. The scope of the present invention is indicated by the claims, not the above description, and all differences within the scope equivalent thereto should be interpreted as being included in the present invention.

1-10. (canceled)

11. A power conversion apparatus comprising:
a first housing;
a first substrate disposed in the first housing; and
a switch module disposed on the first substrate,
wherein the switch module comprises a heat sink and a device unit disposed between the first substrate and the heat sink, and
wherein the heat sink comprises a base on which the device unit is disposed, and a plurality of heat dissipation fins protruding from the base.

12. A power conversion apparatus according to claim 11,
wherein the device unit comprises a frame and a plurality of switches disposed within the frame.

13. A power conversion apparatus according to claim 11,
wherein at least one element is disposed on the first substrate in a region facing one surface of the base.

14. A power conversion apparatus according to claim 11,
wherein the device unit comprises a plurality of device units, and
wherein the plurality of device units are symmetrically disposed on one surface of the base.

15. A power conversion apparatus according to claim 11, further comprising:
an insulating layer disposed between the device unit and the heat sink.

16. A power conversion apparatus comprising:
a first housing;
a first substrate disposed in the first housing;
a switch module disposed on the first substrate; and
a fan module comprising a plurality of fans disposed on one side of the first housing,
wherein the switch module is arranged to overlap with at least two of the plurality of fans in a first direction.

17. A power conversion apparatus according to claim 16,
wherein the switch module comprises a heat sink and a device unit disposed between the first substrate and the heat sink,
wherein the heat sink comprises a base and a plurality of heat dissipation fins protruding from the base, and
wherein the plurality of heat dissipation fins extend along the first direction.

18. A power conversion apparatus according to claim 16,
wherein at least one structure is disposed in at least one region of the switch module facing the fan module and in an opposite region.

19. A power conversion apparatus according to claim 16,
wherein components are disposed on both sides of the switch module on the first substrate.

20. A power conversion apparatus according to claim 16,
wherein the switch module comprises a plurality of switch modules disposed apart from each other on the first substrate, and
wherein at least two of the plurality of switch modules overlap in the first direction.

21. A power conversion apparatus according to claim 20,
wherein in a second direction perpendicular to the first direction, at least one of the plurality of switch modules does not overlap with the other switch modules.

22. A power conversion apparatus according to claim 20,
wherein a switch module among the plurality of switch modules that is disposed closest to the fan module has the largest size.

23. A power conversion apparatus according to claim 20,
wherein a heat generating component is disposed between two adjacent switch modules.

24. A power conversion apparatus comprising:
a first housing;
a second housing coupled to the first housing;
a first substrate disposed in the first housing;
a second substrate disposed in the second housing;
a first switch module disposed on the first substrate; and
a second switch module disposed on the second substrate,
wherein the first switch module and the second switch module are disposed to face each other.

25. A power conversion apparatus according to claim 24, further comprising:
a fan module comprising a plurality of fans disposed on one side between the first housing and the second housing,
wherein at least one of the first and second switch modules overlaps with at least two of the plurality of fans in a first direction.

26. A power conversion apparatus according to claim 24, further comprising:
a third switch module disposed on the second substrate apart from the second switch module,
wherein an inductor is disposed on the first substrate facing the third switch module.

27. A power conversion apparatus according to claim 26, further comprising:
a fourth switch module disposed on the second substrate apart from the third switch module,
wherein the second to fourth switch modules are arranged to overlap in the first direction.

28. A power conversion apparatus according to claim 27,
wherein in a second direction perpendicular to the first direction, at least one of the first to fourth switch modules does not overlap with the others.

29. A power conversion apparatus according to claim 24,
wherein at least one structure is disposed in at least one region of the first and second switch modules facing the fan module and in an opposite region.

30. A power conversion apparatus according to claim 24,
wherein the first and second switch modules each comprise a heat sink and a device unit disposed on the heat sink,
wherein each heat sink comprises a base and a plurality of heat dissipation fins protruding from the base, and
wherein the plurality of heat dissipation fins extend along the first direction.
